(19) United States
(12) Patent Application Publication
(10) Pub. No.: US 2026/0276693 A1
(43) Pub. Date: Sep. 17, 2026

(54) System and method to generate multi-level voltage pulses for electrical insulation testing

(71) Applicant: Ravisekhar Raju, Clifton Park, NY (US)

(72) Inventor: Ravisekhar Raju, Clifton Park, NY (US)

(21) Appl. No.: 19/014,205

(22) Filed: Jan. 8, 2025

(51) Int. Cl. G01R 31/14; G01R 1/20

(52) U.S. Cl. CPC G01R 31/14; G01R 1/206

(57) ABSTRACT

A system and method to generate high voltage pulses for testing of electrical insulation for a device under test (DUT) is presented. The system comprises multiple power electronic building blocks (PEBBs) connected in series, with each PEBB providing a unipolar voltage. The output from the series-connected PEBBs is impressed across the DUT insulation via an output inductor. Some of the PEBBs provide a positive or zero voltage output; while the other PEBBs provide a negative or zero voltage output. The switchings of the PEBBs are timed to allow a resonant half-cycle of current through the output inductor and the effective capacitance of the insulation resulting in a transition of the voltage across the insulation from one level to another. In one embodiment, only the dc bus of a first PEBB is supplied from an external source, while the other PEBBs are fed from the first PEBB via the series chain.

### STATEMENT OF GOVERNMENT INTEREST

Portions of this invention were made with government support under N68335-23-C-0559 awarded by the U.S. Department of Navy. The government has certain rights in the invention.

### BACKGROUND

The present disclosure relates to high voltage pulse generation systems for testing of electrical insulation used in electrical components and equipment. Specifically, the present invention relates to a modular power electronic system for generating multi-level pulses that is comprised of multiple series-connected power electronic building blocks (PEBBs) that are controlled to impress high voltage pulses across the insulation of an electrical device under test (DUT).

Insulation systems in electrical components such as motors, generators, cables, busbars, and connectors are often subject to voltage stresses of high magnitude and steep dv/dt (i.e., rate of change of voltage) when used in conjunction with power electronic converters such as adjustable speed drives. Power electronic converters generally involve switching action resulting in pulse-width-modulated (PWM) or stepped voltage waveforms with high dv/dt.

Insulation is a critical element determining the reliability and life expectancy of electrical equipment and hence there is a need for insulation testing during the design, manufacturing, or servicing stages. Insulation testing is often carried out using hi-pot testers which provide a DC or mains frequency (e.g., 50 or 60 Hz) AC output, but this is inadequate to characterize performance of the insulation under PWM and high dv/dt conditions. Therefore, what is needed are techniques that can provide testing of electrical insulation under such conductions.

U.S. Pat. No. 11,735,357, granted to the applicant, describes a system and method to generate multi-level voltage pulses for electrical insulation testing and is included herein as a prior art reference. In the afore-mentioned prior art, bipolar voltage sources are used in the system which requires the use of a large number of components such as split-dc bus capacitors. The present invention describes novel enhancements that result in a reduced number of components compared to the afore-mentioned prior art.

### BRIEF SUMMARY OF THE INVENTION

Embodiments of the invention provide a system to supply pulsed voltages across the electrical insulation of a device under test for purposes of testing, qualifying, or characterizing the insulation.

In accordance with one aspect of the invention, multiple power electronic building blocks (PEBBs) are configured in series with half of the blocks providing a positive or zero voltage output and the remaining blocks providing a negative or zero voltage output. In the context of this disclosure, a PEBB comprises a half bridge topology with a DC bus with plus and minus terminals on the input side of the PEBB, a capacitor across the DC bus, and two power semiconductor switches placed in series across the DC bus with the junction of the two switches providing a switched output terminal at the output side of the PEBB. The two switches are turned on and off in a complementary fashion to connect the switched output terminal to either the DC plus or the DC minus terminals of the PEBB.

The net output from the series combination of the PEBBs is a multi-level voltage waveform that is controlled by changing the states of the switches in the PEBBs. The multi-level voltage waveform is fed to the device under test (DUT) through an output inductor. The device under test can be, for instance, a motor winding. The insulation of the device under test can be represented as a capacitance with a dissipative resistance component for the purpose of an analytical representation.

According to another aspect of the invention, the afore-mentioned series-connected power electronic building blocks are switched with time delays to transition the voltage across the device under test from one level to another level.

According to a preferred embodiment, substantially half of the PEBBs are switched to initiate the transition of the DUT voltage through the LC circuit consisting of the output inductor and the DUT capacitance. The remaining PEBBs are then switched after a delay substantially close to a half-period of the LC circuit resonance when the output current is near zero. This method of control ensures that the PEBBs are switched at nearly zero current thus reducing switching stresses and losses in the power semiconductor switches used in the PEBBs. Additionally, the LC resonance facilitates generation of voltage pulses across the DUT insulation capacitance by recirculating energy between the DUT insulation capacitance and the output inductor and reducing input power needed from an external source.

According to yet another aspect of the invention, only the dc bus of the first PEBB that is located nearest to ground potential in a series chain of PEBBs is fed by an external power supply, while the dc link of each of the other series-connected PEBBs is replenished from the previous PEBB in the series chain through a diode during the switching operation of the circuit without requiring it to be separately fed from an external power supply.

The terms power electronic building block (PEBB) and power electronic module or module are used interchangeably in this specification.

Various other features and advantages will be made apparent from the following detailed description and the drawings.

### BRIEF DESCRIPTION OF THE DRAWINGS

The present invention is illustrated by way of example and not limitation in the figures of the accompanying drawings in which like references indicate similar elements.

FIG. 1A illustrates, according to prior art, a system to provide multi-level voltage pulses across a device under test, wherein the system consists of bipolar voltage sources connected in series to feed via an output inductor a load that comprises an insulation test piece. The test piece primarily behaves as a capacitor. FIG. 1B illustrates the power converters of FIG. 1A being sequenced to move the voltage across the insulation through various levels according to prior art. FIG. 1C shows the output current waveform through and the voltage across the device under test (DUT) when driven by the prior art system and method of FIGS. 1A and 1B.

FIG. 2A illustrates a system, according to an embodiment of the present invention, wherein two voltage sources, each with a unipolar voltage output, are connected in series. One of the sources is capable of outputting a voltage of +E or zero, while the other source is capable of outputting a voltage of −E or 0. The combined series output of the two voltage sources is connected to a load via an output impedance. The output impedance can comprise an inductor. The load comprises a device under test for its insulation capability. FIG. 2B illustrates the voltage sources of FIG. 2A being sequenced to transition the voltage across the device under test (DUT). FIG. 2C shows the output current waveform through and the voltage across the DUT when driven by the system and method of FIGS. 2A and 2B.

FIG. 3 illustrates a system, according to an embodiment of the present invention, wherein the voltage sources depicted in FIG. 2A are realized with two power electronic building blocks using half-bridge switches.

FIG. 4 illustrates a system, according to an embodiment of the present invention, wherein a first half-bridge located at ground potential feeds a second half-bridge in a series chain through a diode, such that the second half-bridge does not require a feed from a separate power supply.

FIG. 5 illustrates output current, voltage across the insulation, and gating control signals for generating a positive and a negative pulse across the device under test using the system of FIG. 4.

FIG. 6 illustrates a system, according to an embodiment of the present invention, wherein four half-bridges are used in a series chain, and wherein the first half-bridge is charged by a ground-referenced supply and the remaining half-bridges are charged through the chain using diodes that connect adjacent half-bridges.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” or “another embodiment” means that a particular feature, structure, or characteristic described in conjunction with the embodiment can be included in at least one embodiment of the invention.

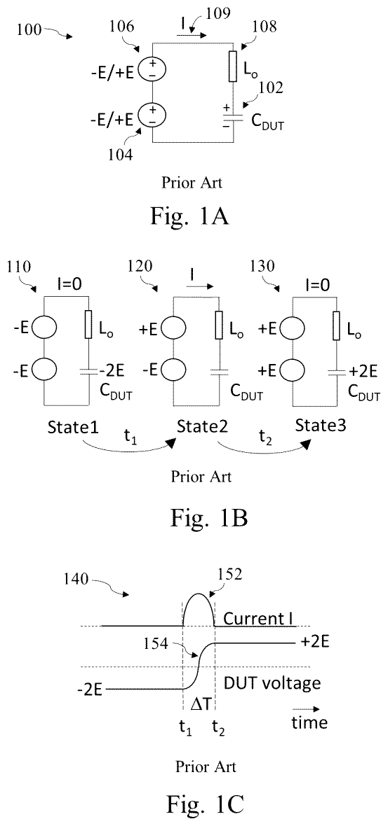

FIG. 1A illustrates, according to prior art, a system, 100, to provide multi-level voltage pulses across a device under test. The system, 100, has a first voltage source, 104, and a second voltage source, 106, that are configured in series with each bridge capable of generating a bipolar output voltage of value +E or −E. The seriesed output is connected across the insulation (device under test), 102, through an output inductor (Lo), 108, which delivers pulsed current, 109, to the device under test. The device under test piece primarily behaves as a capacitor (C_{DUT}).

FIG. 1B illustrates, according to prior art, transitioning of the system in FIG. 1A through various states. The two voltage sources are initially in a state 110, where each source is outputting a voltage of −E and the insulation capacitance is charged to −2 E. A transition is made at time t₁ to state 120 where voltage source 106 is switched from-E to +E output voltage. This results in a LC circuit resonance with the insulation capacitance voltage moving from −2 E to +2 E and the output current going through a half-sinusoidal pulse and ending at near-zero current after the insulation capacitance is charged to +2 E. At the end of this transition at time t₂, the system is moved to state 130 where voltage source 104 is also switched from −E to +E to complete the transition and hold the voltage of the insulation capacitance at a level of +2 E.

FIG. 1C, illustrates according to prior art, waveforms 140 for the voltage 154 across and current 152 through the device under test in FIG. 1A and FIG. 1B. The delay, ΔT, between the switching events of the two voltage sources in FIG. 1B is kept substantially equal to the half-resonance period of the LC elements comprised of the device under test and the output inductor. This results in a half-cycle sinusoidal pulse current, 152, with the voltage 154 having a corresponding sinusoidal transition between levels −2 E and +2 E.

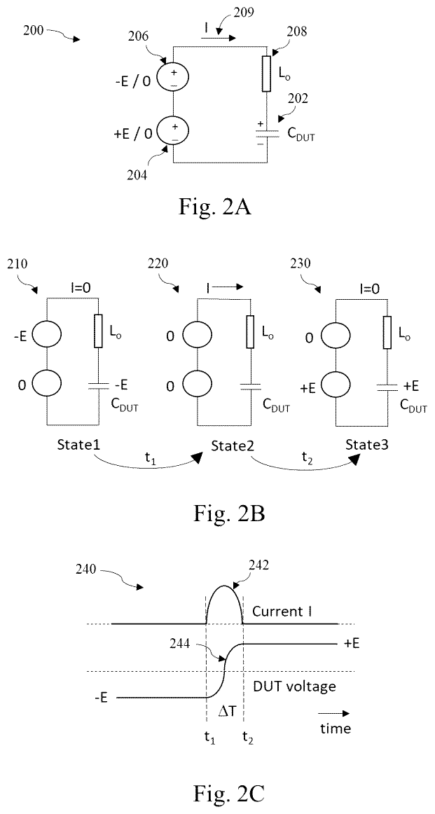

FIG. 2A illustrates a system 200 according to an embodiment of the present invention wherein two unipolar voltage sources 204 and 206 are connected in series with voltage source 204 having a positive or zero output voltage and voltage source 206 having a negative or zero output voltage. The seriesed voltage sources are connected to a device under test 202 through an output impedance 208 which provides a path for a pulsed current 209. The output impedance can comprise an inductor. In comparison to the prior art, each individual voltage source needs to be capable of only outputting a unipolar voltage which can reduce component count and cost.

FIG. 2B illustrates, according to an embodiment of the present invention, transitioning of the system in FIG. 2A through various states. The two voltage sources are initially in a state 210, where voltage source 204 is providing a zero voltage and voltage source 206 is providing a voltage of −E. each source is outputting a voltage of −E and the insulation capacitance is charged to −2 E. A transition is made at time t₁ to state 220 where voltage source 206 is switched from −E to a zero output voltage. This leads to an LC circuit resonance due to the inductance of the output impedance and the insulation capacitance of the DUT and results in the device under test 202 voltage moving from −E to +E. The output current 109 goes through a half-sinusoidal pulse ending at near-zero current when the device under test is charged to +E. At the end of this transition at time t₂, the system is moved to state 230 where voltage source 204 is switched from a voltage of zero to +E to complete the transition and hold the voltage of the device under test at a level of +E. A similar transition in reverse is undertaken for negative going output pulses.

FIG. 2C, illustrates, according to an embodiment of the present invention, waveforms 240 for the voltage 244 across and current 242 through the device under test in FIG. 2A and FIG. 2B. The delay, ΔT, between the switching events of the two voltage sources in FIG. 2B is kept substantially equal to the half-resonance period of the LC elements comprised of the device under test and the output inductor. This results in a half-cycle sinusoidal pulse current, 242, with the voltage 244 having a corresponding sinusoidal transition between levels −E and +E.

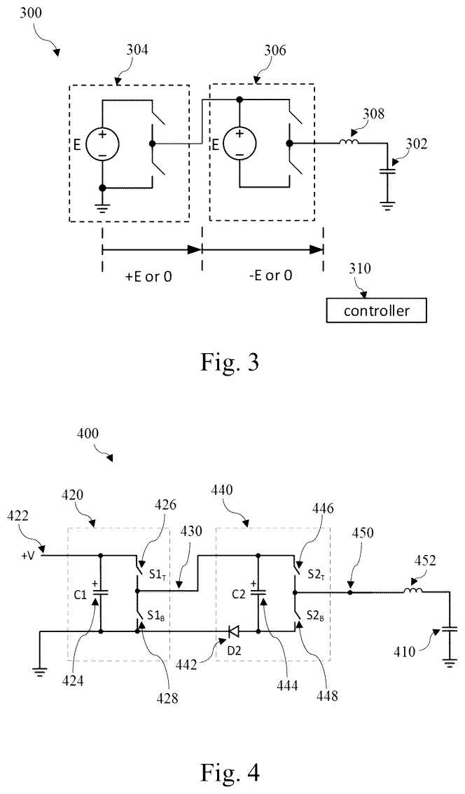

FIG. 3 shows a schematic with two series-connected power electronic building blocks (PEBBs), 304 and 306, each further comprising a half-bridge with two switches, as a means to implement the system shown in FIG. 2A. PEBB 304 produces an output voltage of +E or zero with respect to ground based on the position of its switches, while PEBB 306 adds a series voltage of −E or zero based on the position of its switches. The net output from the two PEBBs is fed through an output inductor 308 to the device under test 302. A controller 310 is used for timing the turn-on and turn-off of the switches in the PEBBs.

FIG. 4 shows a schematic 400 with two series-connected power electronic building blocks (PEBBs), 420 and 440, each of which comprises a dc bus capacitor and two switches in a half-bridge configuration. The dc bus capacitor 524 in PEBB 420 is ground-referenced at one terminal and charged from an external power supply connected to the other terminal, 422. When switch 426 is on, capacitor 444 in PEBB 440 is charged from capacitor 524 in PEBB 420 through diode 442. Switches 426 and 428 in PEBB 420 are operated in a complementary fashion to produce either a positive voltage or zero voltage at terminal 430 with respect to ground. PEBB 440 which is next in the series connection comprises a dc bus capacitor 444 which is charged from PEBB 420 through terminal 430 and diode 442 when switch 426 is on. Switches 446 and 448 are operated in a complementary fashion to produce a zero or a negative voltage between terminals 450 and 430. The net output from the two PEBBs is a positive, negative or zero voltage at the terminal 450 which is fed to an output inductor 452 and a device under test (DUT) 410.

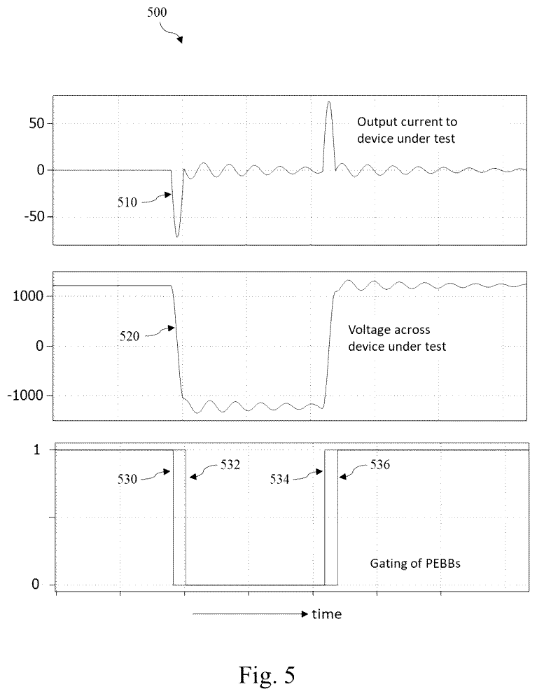

FIG. 5 illustrates, according to one embodiment of the present invention, the waveforms, 500, for operation of the circuit shown in FIG. 4. The output current, 510, featuring an LC resonance is shown at the top graph, while the voltage, 520, impressed across the device under test is shown in the middle graph. The waveforms in the bottom graph represent the gating signals for the half-bridge of the two PEBBs with a logic level of 1 indicating the top switch in a half-bridge being on and logic level of 0 indicating the bottom switch in a half-bridge being on. Waveforms 530 and 536 represent the switching state transitions of PEBB 420, while waveforms 532 and 534 represent the switching state transitions of PEBB 440. In FIG. 5, the switching transitions for PEBBs 420 and 440 are offset by a time substantially equal to an LC resonance half-period corresponding to the output inductor 452 and the insulation capacitance of DUT 410.

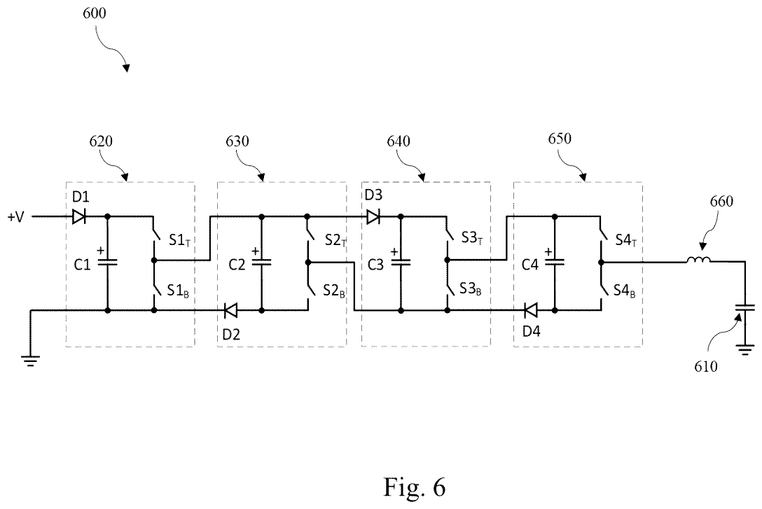

FIG. 6 illustrates, according to an embodiment of the present invention, a system, 600, with multiple PEBBs, 620, 630, 640 and 650 connected in series to provide a net pulsing output voltage to the DUT 610 through inductor 660. Each of the PEBBs is capable of adding a unipolar voltage in the series chain with some of the PEBBs providing a positive or zero voltage and the remaining PEBBs providing a negative or zero voltage. The dc link of the first PEBB, 620, is fed from an external source with the subsequent bridges kept charged through the series chain of PEBBs and diodes D2, D3, and D4 in a manner similar to that described for the case with two PEBBs in FIG. 4. In FIG. 6, adjacent PEBBs in the series chain have alternating voltage polarity, but this need not be the case for other embodiments of the present invention.

Although PEBBs based on half-bridges are described and illustrated in the figures, the PEBBs can also be based on three-level or other multi-level structures. With multiple PEBBs, only a portion of the PEBBs can be switched during a particular pulse such that the voltage across the DUT can take on multi-level values with steps that are at intermediate levels in between the full series voltage of the PEBBs. As yet another variation, a combination of unipolar and bipolar PEBBs can be connected in series to provide a multi-level pulsed output voltage.

The foregoing description of exemplary embodiments of the invention has been presented for the purposes of illustration and description. It is not intended to be exhaustive or to limit the invention to the precise forms disclosed. It will be recognized by those skilled in the art that many modifications and variations are possible without departing from the essential scope of the invention. It is, therefore, to be understood that the scope of the invention is not limited to the particular embodiments disclosed, and that the invention will include all embodiments falling within the scope of the claims appended hereto.

What is claimed is:

1. A system providing a pulsed output voltage for electrical insulation testing of a device under test (DUT);
wherein the system comprises multiple power electronic building blocks (PEBBs) connected in a series chain; and
wherein a total output voltage from the PEBBs connected in the series chain is impressed upon said DUT through an output impedance; and
wherein each of the PEBBs provides a unipolar voltage output; and
wherein at least one of the PEBBs provides a unipolar voltage output of positive or zero level; and
wherein at least another one of the PEBBs provides a unipolar voltage output of negative or zero level.

2. The system of claim 1;
wherein each of the PEBBs comprises a dc bus capacitor and two switches in a half-bridge configuration.

3. The system of claim 1, wherein the output impedance comprises an inductor.

4. The system of claim 1, wherein the dc bus capacitor in a first PEBB located at or nearest to ground potential in the series chain is charged by an external power supply and the dc bus capacitors in the remaining PEBBs in the series chain are charged via the series chain from the first PEBB.

5. The system of claim 4, wherein the dc bus capacitors in the remaining PEBBs in the series chain are charged from the first PEBB through a set of diodes, each of which connects an adjacent pair of PEBBs in the series chain.

6. The system of claim 1, wherein a first set of the PEBBs are switched to initiate an output voltage change across the DUT followed by a time delay after which a second set of the PEBBs are switched to complete the output voltage change across the DUT.

7. The system of claim 6, wherein the time delay between the switching of the first set of the PEBBs and the second set of the PEBBs is substantially equal to a half-period of a resonant circuit formed by the output impedance and the DUT.
